(19) United States
(12) Patent Application Publication
(10) Pub. No.: US 2004/0045596 A1
(43) Pub. Date: Mar. 11, 2004

(54) Flat plate panel solar electrical generators and methods

(76) Inventor: Paul Lawheed, San Diego, CA (US)

Correspondence Address: Mr. Lynn G. Foster, 602 E. 300 S., Salt Lake City, UT, 84102, US

(21) Appl. No.: 10/616,200

(22) Filed: Jul. 9, 2003

Related U.S. Application Data
(63) Continuation-in-part of application No. 10/458,917, filed on Jun. 10, 2003.
Application No. 10/458,917 is a continuation of application No. 10/251,709, filed on Sep. 21, 2002, now abandoned.
Application No. 10/251,709 is a continuation of application No. 09/867,196, filed on May 29, 2001, now Pat. No. 6,498,290.

(51) Int. Cl. H01L 25/00

(52) U.S. Cl. 136/246

(57) ABSTRACT

Novel flat plate solar panels are disclosed, which, using low profile multiple axes tracking, keep the surface of each flat plate panel upon which rays of the sun are impinged essentially perpendicular to those rays enabling a higher rate of conversion to electrical energy and a long interval each day during which conversion of sunlight to electricity is accommodated. Side peripheral sunlight deflectors redirect rays of sunlight perpendicular to the face fo the flat plate panel but directly adjacent to and somewhat out of alignment with the impingement surface of the flat plate panels upon the impingement surfaces thereby concentrating a greater amount of sunlight to produce a greater quantity of electricity. A cooling system for the flat plate panels, using circulated fluid is disclosed whereby the thermal energy so obtained may be used to perform work to make the system more cost effective.

### CONTINUITY

This application is a continuation-in-part of my copending U.S. patent application Ser. No. 10/458,917, filed Jun. 10, 2003 which is a continuation of U.S. patent application Ser. No. 10/251,709, filed Sep. 21, 2002, now U.S. Pat. No. ______, which is a continuation of U.S. patent application Ser. No. 09/867,196 filed May 29, 2001, now U.S. Pat. No. 6,498,290.

### FIELD OF THE INVENTION

The present invention relates generally to transformation of sunlight into electricity and, more particularly to improvements in flat plate panel solar electrical generators by which a greater magnitude of sunlight is perpendicularly concentrated on the flat plate panel to increase the amount of electricity derived therefrom and from which thermal energy is beneficially obtained.

### BACKGROUND

Flat plate panel conversion of sunlight to electricity is well known. Typically, one or more flat plate panels are mounted in a fixed position on the roof of a building or other exposed location. With the possible exception of a few seconds per day, the rays of the sun are not perpendicular but rather angularly disposed in two respects (altitude and azimuth) to the surface of each stationary flat plate panel upon which the sunlight is impinged. This lack of perpendicularity results in inefficient generation of electricity because some of the sunlight is deflected off the impingement face of each flat plate panel. Also, no use is made of the rays of sunlight which are directly adjacent to but somewhat out of alignment with the impingement surface of each flat plate panel.

While pedestal-based single or dual axis tracking of a large bank of flat plate panels, comprising a plurality of rows, around a single horizontal axis and a single vertical axis has been proposed, the resulting high vertical profile makes rotation awkward, requires expensive and strong support structure and subjects the panels and the support structure to high stress due to the weight of the assembly and large wind loads sometimes imposed thereon. Damage results in significant expenses of repair and lack of productivity during downtime.

Further, the efficiency of the solar elements of prior art flat plate panels is low to begin with and the rate at which electricity is produced is further reduced by reason of the high temperatures caused by the rays of the sun striking the flat plate panel and the process by which electricity is generated using solar cells. No constructive use is made of the thermal energy so generated. This low efficiency is exacerbated by the high cost of commercially available solar cells.

### BRIEF SUMMARY AND OBJECTS OF THE PRESENT INVENTION

In brief summary, the present invention alleviates certain prior problems associated with flat plate panel generation of electricity from sunlight. The present invention, using low profile multiple axes tracking, keeps the surface of each flat plate panel upon which rays of the sun are impinged essentially perpendicular to those rays enabling a higher rate of conversion to electrical energy and a long interval each day during which conversion of sunlight to electricity is accommodated.

Also, using one or more side peripheral sunlight deflectors, rays of sunlight perpendicular to the face of the flat plate panel but directly adjacent thereto and somewhat out of alignment with the impingement surface of the flat plate panel are redirected or deflected upon the impingement surface thereby concentrating a greater amount of sunlight to produce a greater quantity of electricity.

In addition, the efficiency ofthe solar elements ofthe flat plate panels is enlarged by uniquely cooling the flat plate panels using circulated fluid, whereby the thermal energy so obtained may be used to perform work to make the system more cost effective.

With the foregoing in mind, it is a primary object of the present invention to alleviate prior problems associated with flat plate panel generation of electricity from sunlight.

Another paramount object is to track the sun with one or more flat plate panel generators along a horizontal axis of rotation for the one or each row of flat plate panels so that the profile is low and the surface or face of each flat plate panel upon which rays of sunlight is impinged is kept essentially perpendicular to the rays, thereby eliminating defection loss of sunlight.

A further object of value is the provision of one or more side deflectors at the periphery of each flat plate panel such that rays of sunlight directly adjacent to but somewhat out of alignment with the impingement surface of each flat plate panel are redirected or deflected upon the impingement surface to produce a greater quantity of electricity.

An object of importance is obtaining increased efficiency of electrical production per unit of time from solar elements of flat plate panel solar generators through cooling, using a circulating fluid, the thermal energy of which can be used to perform work.

Another dominate object ofthe present invention is to provide a novel flat plate panel system, comprised of a low profile multiple axes tracking feature, having a low vertical profile.

A further significant object is the provision of a novel flat plate panel sunlight-to-electricity converter which can be inverted during times of darkness and/or bad weather.

These and other objects and features of the present invention will be apparent from the detailed description taken with reference to accompanying drawings.

### BRIEF DESCRIPTION OF THE DRAWINGS

FIG. 1 is a fragmentary perspective of a flat plate panel for direct conversion of sunlight to electricity, embodying improvements according to the present invention;

FIG. 2 is fragmentary perspective of an existing flat plate panel retrofit with improvements according to the present invention;

FIG. 3 is an enlarged cross section of the embodiment of FIG. 1 further encapsulated in an evacuated enclosure;

FIG. 4 is an enlarged cross section of the embodiment of FIG. 2 further encapsulated in an evacuated enclosure;

FIG. 5 is a fragmentary perspective of a flat plate panel assembly equipped with peripheral side panels by which sunlight adjacent to but out of alignment with the face of a flat plate panel is deflected onto the face;

FIG. 6 is a fragmentary perspective of the flat plate panel assembly of FIG. 5 shown in an inverted, stowed position to prevent weather-related contamination during times of darkness and inadequate sunlight; and

FIGS. 7 and 8 are fragmentary diagrammatic representations of the manner in which the panels of FIGS. 1-4 and 5-6 may, respectively, utilize multiple axes tracking to keep the face of each associated flat plate panels generally perpendicular to the rays of the sun.

### DETAILED DESCRIPTION OF THE ILLUSTRATED EMBODIMENTS

This disclosure is of only some of many possible embodiments of the present invention and is directed broadly to the field of flat plate panel generation of electricity from solar energy. The embodiments of the invention, as depicted in the drawings, is concerned with obtaining a greater concentration of sunlight on flat plate panels to increase the amount of electricity so derived. The present invention, broadly, and as illustrated in the drawings, is also concerned with cooling of flat plate panels such that thermal energy so derived may be beneficially utilized thereby making flat plate panels more cost effective. The efficiency of flat plate panels, in accordance with the present invention, is further enhanced by utilizing a multiple axis tracking system whereby the face of each flat plate panel is maintained in a state of substantial perpendicularity to the rays of the sun thereby reducing the amount of lost solar energy heretofore angularly deflected off from the face ofprior flat plate panels so as to be unavailable for conversion to electricity.

Prior flat plate panels have, to a large extent, been the standard in the industry, typically being mounted in a fixed position on a roof a building or other exposed location so as to face south without the capacity to track the sun. The rays of sunlight adjacent to but out of alignment with the face of each flat plate panel until now have not been utilized to enhance the concentration of sunlight on the impingement face of each flat plate panel to increase production of electricity.

Though inherently not cost effective, it has been found that by utilizing a circulated coolant so as to reduce the temperature of the solar cells comprising the flat plate panels, more electricity is generated per unit of time and the resulting thermal energy carried away by the coolant can be used to do work, making the system and process more cost effective. This is relatively important in light of the high cost of commercially-available solar cells.

By using one or more side sunlight deflectors, peripherally disposed in respect to an associated flat plate panel, rays of sunlight perpendicular to but offset from the face of the flat plate panel and directly adjacent thereto are redirected onto the impingement surface or face of the flat plate panel delivering a greater amount of sunlight to the solar cells for production of to a greater quantity of electricity.

By avoiding acute angle deflection of sunlight from the face of each flat plate panel through maintaining the above-mentioned perpendicularity, a longer interval during each day is made available by the present invention for conversion of sunlight to electricity without loss of sunlight due to angular deflection. Of particular importance is the preservation of a low vertical profile in systems embodying the principles of the present invention. This avoids the costs of and high maintenance to high strength support structure and avoids the stress caused by rotation of heavy structural components and by potentially damaging wind loads on multiple rows of flat plate panels collectively rotated about a single horizontal axis. The low profile of the present invention is accomplished by use of a single flat plate panel or a single row of flat plate panels which rotate around a single horizontal axis or several rows of flat plate panels, each having a separate horizontal axis.

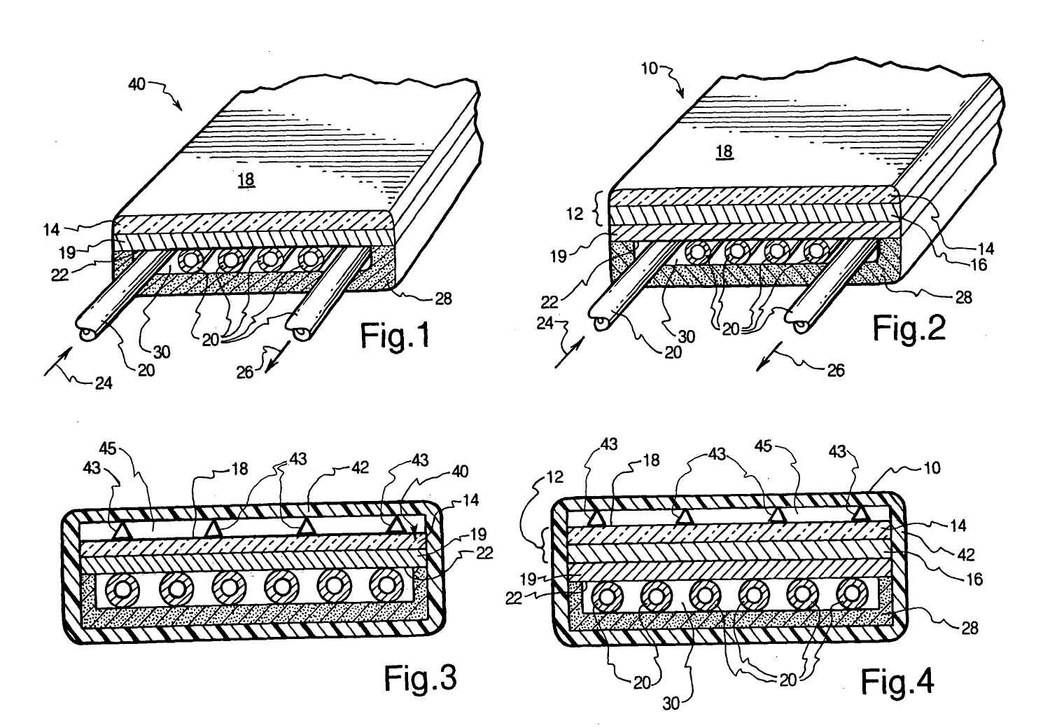

Detailed reference is now made to the drawings wherein like numerals are used throughout to designate like parts. The flat plate panels shown in FIGS. 1 and 2 emphasize, respectively, the manner in which such panels, in accordance with principles of the present invention, may be originally manufactured (FIG. 1) or retrofit by modifying an existing prior flat plat panel to further comprise the present invention (FIG. 2).

FIG. 2 illustrates a solar assembly, generally designated 10, comprised of prior art elements coupled with elements of the present invention. More specifically, the assembly 10 is comprised of a prior art flat plate panel 12 comprised of a solar cell layer 14, by which solar energy is converted to electrical energy and a backing or structural support layer 16 on which the layer 14 is mounted in any suitable way.

Typically, the layer 14 is comprised of an array of commercially-available silicon solar cells by which the solar energy is converted to electrical energy, the solar cells being arranged in a suitable pattern. The entire laminate panel 12 is commercially available. For example, Shell produces such a solar flat plate panel, identified as SOLAR MODULE SHELL SM55 which may be used with the present invention. Typically, commercially available panel assemblies 12 are placed in a static rigid frame disposed at fixed angles to both the horizontal and the vertical so that the face 18 of the layer 14 angularly faces the south in a fixed position. Thus, with the exception of no more than a brief period of time daily, the surface 18 of each layer 14, upon which the rays of sun impinge is non-perpendicular to the rays. The rays strike the surface 18 at an acute angle and, consequently, a certain percentage of this solar energy is deflected from surface 18 away from the layer 14, without accommodating conversion to electricity. Obviously, in the early morning and late afternoon the acute angle of the rays of sunshine striking surface 18 is so severe that a very high percentage of the rays are deflected away from layer 14, without conversion to electricity.

The backing layer 16 holds the layer 14 structurally in a planar condition, reducing the likelihood of fracture, fatigue, failure due to impact loads and through flexure and overall provides strength and rigidity for the layer 14.

To retrofit a preexisting panel 12 (comprised of layers 14 and 16), a layer 19, as illustrated in FIG. 2, is applied to or superimposed over the bottom surface of layer 16. Element 19 is commercially-available and is a bifunctional layer. While shown as being of uniform thickness, layer 19 does not necessarily have to have a single thickness. The thickness may vary and, indeed, may constitute a coating having a variable thickness, depending upon the manner in which the coating is applied. The element 19 first functions as a dielectric in that electrical energy generated at layer 14 is prohibited from passing through element 19. In addition, element 19 further functions to accommodate heat transfer from layers 14 and 16 across element 19 to the underside of element 19, as illustrated in FIG. 2.

A serpentine-shaped metal tube 20, which may comprise copper or another thermally-conductive metal, is disposed contiguous with the undersurface 22 of the layer 19 so that thermal energy passing through layer 19 is communicated to the metal tubing 20 and thence to a suitable coolant circulated through the hollow interior of the serpentine-shaped tube 20. Entry of influent coolant into the tube 20 is diagrammatically illustrated at arrow 24 in FIG. 2, while effluent coolant, carrying away thermal energy from the assembly 10, is diagrammatically illustrated at arrow 26. The effluent coolant, depicted by arrow 26 in FIG. 2, may be used to perform any number of various types of work, including, but not limited to, heating buildings, generating electricity and as a fluid in a heat exchanger. Profitable use of thermal energy makes it possible to derive additional income through use of the present invention.

While not mandatory, the tube 20 is desirably thermally insulated. FIG. 2 illustrates a U-shaped insulation element 28 surrounding three sides of the tubing 20 and defining an interior compartment 30 immediately below the layer 18 in which the serpentine tubing 20 is located.

Reference is now made to FIG. 1, which illustrates a non-retrofit or an originally manufactured solar assembly, generally designated 40. Assembly 40 is in all respects identical to assembly 10, described in conjunction with FIG. 2, except the backing layer 16 has been eliminated. The assembly 40 functions in the same manner as described above in conjunction with assembly 10. Assembly 40 or a series of such assemblies are adapted to be placed in support frames to allow rays of sunshine to be impinged upon surface 18 in substantial perpendicularity thereto, as explained herein in greater detail.

Reference is now made to FIGS. 3 and 4. The assembly shown in FIG. 3 is identical to the assembly 40 shown in FIG. 1, with two exceptions, i.e. (1) the assembly 40 is encapsulated or enclosed within a light transmitting synthetic resinous envelope 42, the interior of which is evacuated or vacuumized using commercially available technology, and (2) spacers 43 are provided between the envelope 42 and the surface 18 to create a space 45 which aids in evacuation.

Likewise, the assembly of FIG. 4 is identical to the assembly 10 shown in FIG. 2, with two exceptions, i.e. (1) the encasement of assembly 10 within a light transmitting synthetic resinous envelope 42, the interior of which is vacuumized or evacuated, and (2) spacers 43 are provided between the envelope 42 and the surface 18 to create a space 45 which aids in evacuation. Evacuation produces a greater transfer of heat to the fluid circulated in tube 20.

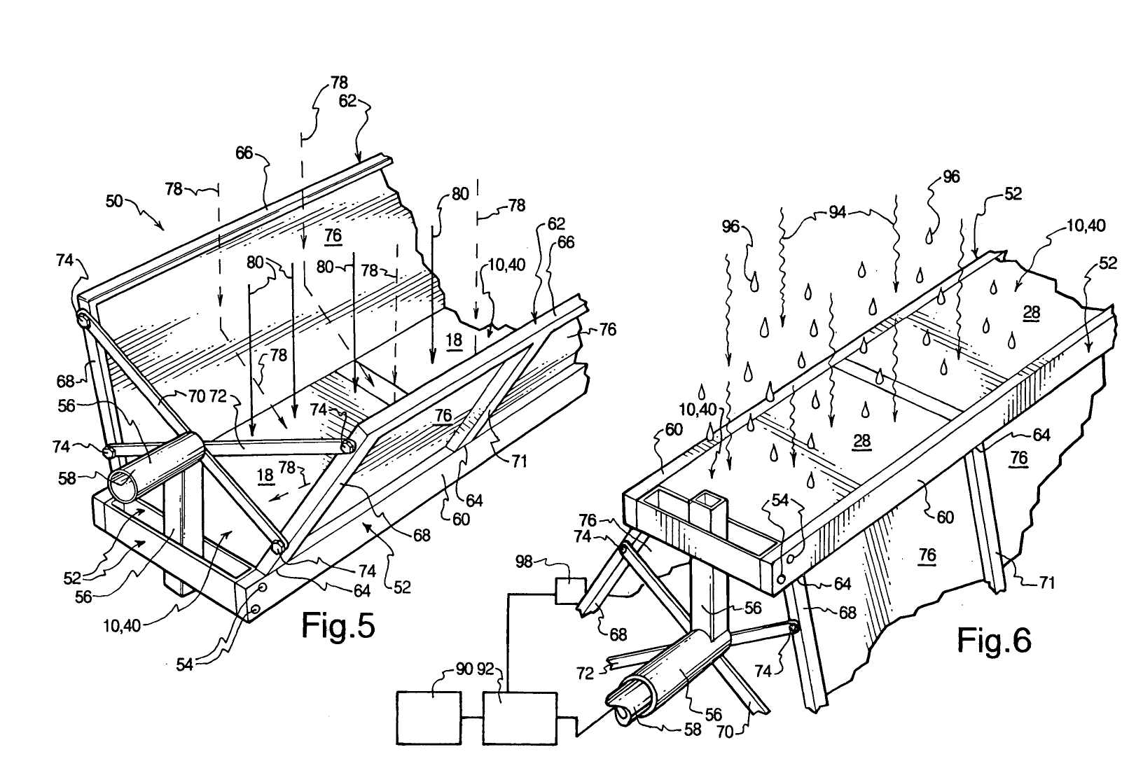

Reference is now made to FIG. 5, which illustrates a further aspect of the present invention by which a greater measure of sunlight is concentrated upon each impingement face 18 of one or a series of flat plate panels of assemblies 10, assemblies 40 or both. The solar assembly of FIG. 5 is generally designated 50 and comprises a rectangular frame 52 of any suitable material having a small vertical dimension and a much larger horizontal dimension, when viewed as depicted in FIG. 5. Preferably the frame 52 is formed of metal members suitably secured together by fasteners 54, which may be screws or bolts, or in some other way. An L-shaped dog-leg axle receptor 56 is secured to each end of the frame 52 and accepts at the sleeve of receptor 56 disposed at each end, an axle 58 in non-rotatably relation. Thus, when the two end axles 58 are rotated, the frame 52 and the series of assemblies 10 and/or 40 carried by the frame 52 are correspondingly rotated for the purpose of preserving perpendicularity with rays of the sun, as explained herein in greater detail.

The frame 52 comprises two spaced parallel longitudinally directed side rails 62. The perpendicular distance between the side rails 62 is essentially equal to the width of the panels 10, 40, which are placed therebetween. A sunlight deflecting section 62 is joined to each rail 62, using any suitable commercially available fastening technique, at interface sites 64. When frames 52 and 62 are both formed of steel or other suitable metal, welding at sites 64 may be utilized. Each frame 62 comprises a distal, longitudinally directed frame element 66 and spaced end cross braces 68 and intermediate cross braces 71. Each frame 62 may be comprised of separate elements or members suitably fastened together, such as by welding or use of commercial fasteners, so as to comprise a rigid, elongated and rectangular frame.

In the assembled condition, as shown best in FIG. 5, the spaced frames 62 are upwardly divergent and, therefore, each forms an acute angle in respect to the rays of the sun, the acute angle being appropriately selected by those of skill in the art to accommodate delivery of a greater amount of sunlight to the impingement face 18 of each flat plate panel 10, 40. The selected acute angle for the two associated deflection frames 62 is maintained by a pair of diagonal support members 70 and 72 at each end. The members 70 and 72 rigidly connect between the end cross members 68 disposed at each end of a row of flat plate panels 10, 40. As best shown in FIG. 5, the diagonal supports 70 and 72 are anchored at their respective ends to both cross members 68 utilizing bolts 74. Thus, the panel-receiving frame 52 and the angularly disposed, peripherally located upwardly diverging frames 62 form a rigid assembly.

Mounted within each frame 62 is a mirror 76. Each mirror 76 comprises an angular surface adjacent to surfaces 18 accommodating deflection of rays 78 of sunlight adjacent to but somewhat out of direct alignment with the surfaces 18. In reference to FIG. 5, sunlight directly impinging upon surfaces 18 without deflection is shown by lines 80.

As explained herein in greater detail, the row 50 of flat plate panels (FIG. 5) with side peripheral deflectors is rotated around the center line of the aligned pairs of axles 58 to assist in maintaining perpendicularity between the surfaces 18 and the rays of sunlight 80.

To protect the surfaces 18 and the interior deflecting surfaces of mirrors 76, the row 50 of flat plate panels 10, 40 and side peripheral deflectors may be rotated to a stowed, sleep or inactive protected position as shown in FIG. 6. While this may be done manually, it may be achieved automatically as shown in FIG. 6. The mechanism of FIG. 6 comprises a light detector or photocell 90, which detects darkness and during adverse weather conditions when inadequate sunlight exists to accommodate generation of electricity at panels 10, 40. When either of these events occurs, sensor 90 causes motor 92 to rotate the aligned pair of axles 58 to thereby invert the assembly 50 from a position disposed at angles to both the vertical and the horizontal to the inverted position of FIG. 6. Thus, inadequate sunshine 94 does not reach the surfaces 18 of the flat plate panels 10, 40 and rain 96 and/or other adverse weather does not contaminate surfaces 18 or the deflecting surfaces of mirrors 76. When the assembly 50 reaches the stowed position of FIG. 6, a limit switch 98 causes the motor 92 to discontinue rotation of the axles 58.

When adequate sunlight returns at sunrise or when adverse weather is over, the sensor 90 causes the reversible motor 92 to rotate the assembly 50 oppositely so that it is oriented such that the faces 18 of the flat plate panels 10, 40 have perpendicularity with the rays of the sun.

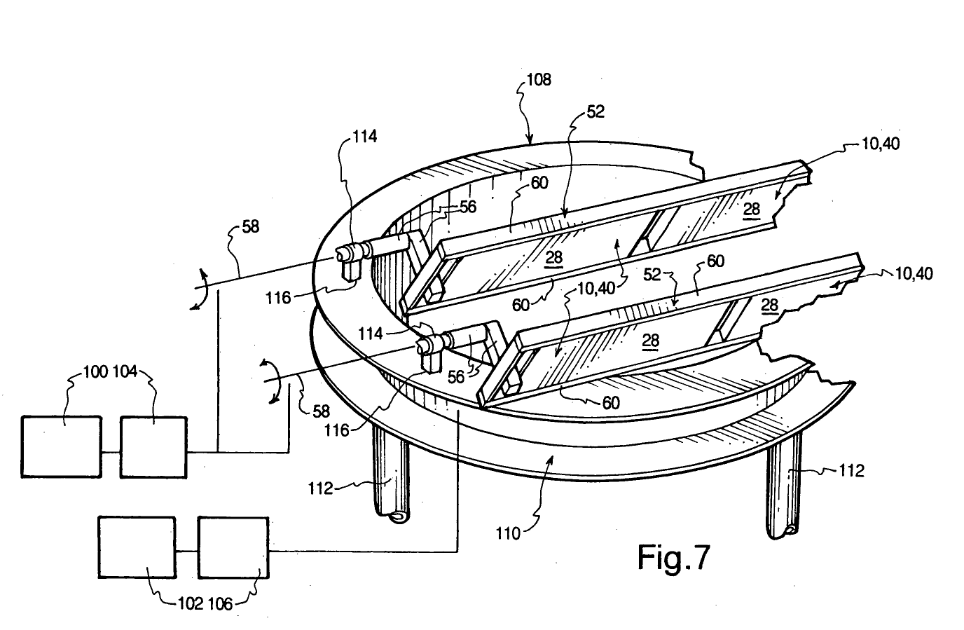

Reference is now made to FIG. 7 which illustrates use of the flat plate panels of FIGS. 1 through 4, without side deflectors, in conjunction with a multiple axis tracking system. The tracking system may be the one disclosed in U.S. Pat. No. 6,498,290, the disclosure of which is incorporated by reference. The combination of FIG. 7, as can be seen by observation, presents a very low profile, making it unnecessary to use expensive and high maintenance structural supports and whereby wind loads and weight do not cause excessive stress.

Basically, the diagrammatic representation of FIG. 7 comprises an azimuth sunlight detector 100 and a latitude sunlight detector 102. Detectors 100 and 102 are commercially available. Detector 100 ascertains when the angle of incidence of surfaces 18 of the flat plate panels 10, 40 is other than perpendicular to the rays of the sun. When a condition of azimuth non-perpendicularity occurs, sensor 100 causes motor 104 to rotate each pair of axles 58 changing the angle at which surfaces 18 are disposed in direct azimuth alignment with the rays of the sun.

Simultaneously, the latitude detector 102 ascertains when the rotor support structure 108, upon which the solar generators are mounted, is disposed such that the surfaces 18 of the flat plate panels are not perpendicular with the sun from a latitude point of view. In this case, the sensor 102 causes a motor 106 to rotate the rotor 108 upon a stater support 110 to restore latitude perpendicularity. The rotor stater support 110 is shown in FIG. 7 as having a plurality of ground or floor-engaging legs 112.

The axles 58 turn in bearings 114, the housings for which are rigidly secured at sites 116 to the rotor 108.

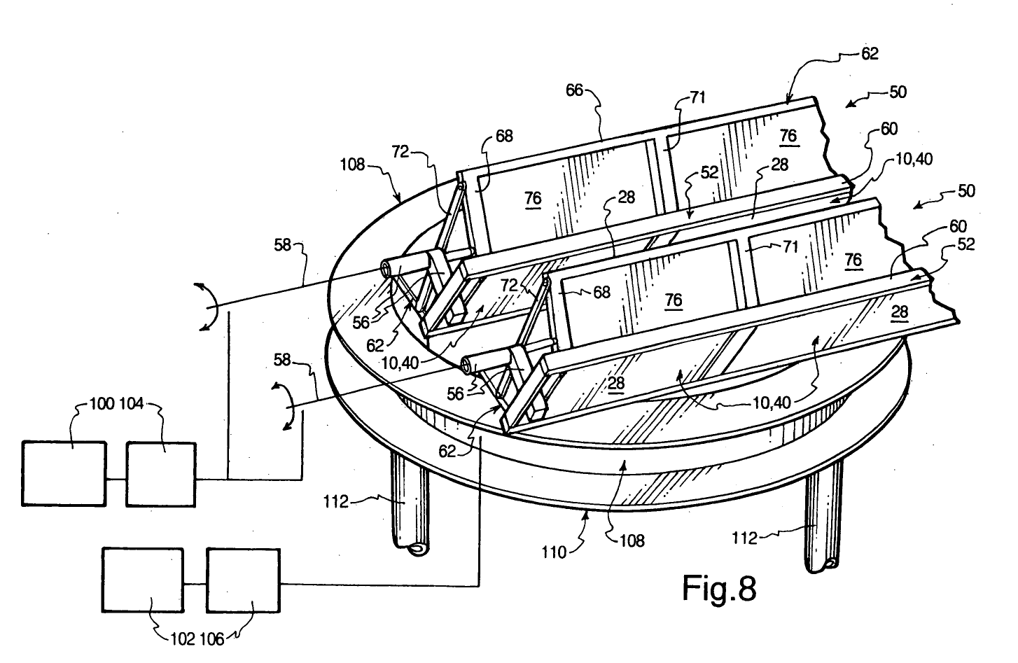

Reference is now made to FIG. 8, which shows the solar generating assemblies 50 arranged in a plurality of rows supported by and operated upon the rotor 108, in the manner described above in conjunction with FIG. 7. Since the assembly 50 has heretofore been described in conjunction with FIG. 5 and the tracking system has heretofore been described in conjunction with FIG. 7, no further description of the components or operation of the embodiment of FIG. 8 is necessary for a clear understanding on the part of those skilled in the art.

The invention may be embodied in other forms without departing from the spirit or essential characteristics thereof. The present embodiments are therefore to be considered in all respects as illustrative and not restrictive, the scope of the invention being indicated by the appended claims rather than by the foregoing description, and all changes which come within the meaning and range of equivalency of the claims are therefore intended to be embraced therein.

What is claimed and desired to be secured by Letters Patent is:

1. A combination comprising:
a flat plate panel converter having a top upon which sunlight is impinged, the converter deriving electricity from sunlight;
a cooling mechanism disposed beneath the flat plate panel converter to which heat created at the converter is dissipated.

2. A combination according to claim 1 wherein the cooling mechanism comprises a fluid-flow passageway to which the heat from the converter is transferred.

3. A combination according to claim 2 wherein the passageway is defined by at least one thermally conductive metal tube.

4. A combination according to claim 1 wherein the configuration of the metal tube is serpentine.

5. A combination according to claim 3 further comprising a thermally conductive metal sheet disposed above the metal tube.

6. A combination according to claim 1 further comprising a layer of material interposed between the cooling mechanism and the converter, the layer comprising material which is both dielectric and thermally conducting.

7. A combination according to claim 1 further comprising thermal insulation surrounding at least part of the cooling mechanism.

8. A combination according to claim 1 further comprising a support layer for the converter superimposed over the cooling mechanism.

9. A combination comprising:
at least one flat plate panel solar element comprising a surface upon which sunlight is impinged, the solar element converting sunlight to electricity;
a sunlight concentrator comprising at least one deflection adapted to extend angularly skyward away from a peripheral location adjacent to the surface ofthe solar element and from which rays of sunlight offset from but adjacent to the surface of solar element are deflected therefrom against the surface of the solar element whereby a greater quantity of electricity is obtained.

10. A combination according to claim 9 wherein the sunlight concentrator comprises at least two opposed upwardly diverging angular mirrors disposed peripherally to the surface of the solar element to concentrate more sunlight on the surface.

11. A combination according to claim 9 wherein the surface of the at least one solar element is generally flat, the combination further comprising a heat transfer system disposed beneath the solar element comprising a passageway through which fluid is passed to transfer heat from the solar element to the fluid.

12. A combination according to claim 9 wherein the passageway is defined at least in part by a thermally conductive serpentine metal tube.

13. A combination according to claim 12 further comprising a thermally conductive sheet interposed between the solar element and the metal tube.

14. A combination according to claim 11 further comprising material interposed between the solar element and the heat transfer system the material being thermally conductive but electrically non-conductive.

15. A combination according to claim 9 further comprising a support backing upon which the solar element is superimposed.

16. A combination according to claim 9 further comprising a multiple axes tracking system by which the solar element is placed and retained essentially perpendicular to the sun.

17. A combination according to claim 9 further comprising a mechanism by which the combination is generally inverted during times of low and no sunlight to protect the surface and deflector for environmental contaminate.

18. A combination comprising:
a flat plate panel sunlight-to-electricity converter;
a cooling system disposed next to the flat plate panel away from the sun;
a multiple axes tracking system by which an exposed surface of the flat panel is normally maintained essentially perpendicular to the sun during daylight hours.

19. A combination according to claim 18 further comprising at least one angularly-disposed side board reflector whereby adjacent sunlight not aligned with the exposed surface of the flat panel is deflected onto the exposed surface.

20. A combination according to claim 18 wherein the combination presents a low vertical profile.

21. A method of deriving electricity from sunlight comprising the acts of:
impinging sunlight upon a surface of a flat plate panel;
converting the impinged sunlight to electricity while generating heat at the flat plate panel;
transferring heat from the flat plate panel to elevate the temperature of a fluid circulated adjacent to an underside of the flat plate panel.

22. A method according to claim 21 comprising the further act of utilizing the elevated temperature of the fluid to do work.

23. A method according to claim 21 comprising the further act of passing the heat from the flat plate panel to the fluid across a dielectric heat transferring medium.

24. A method according to claim 21 wherein the impinging act comprises impinging sunlight both directly and through angular side panel deflection upon the surface of the flat plate panel.

25. A method of deriving electricity from sunlight comprising the acts of:
impinging sunlight upon a surface of a flat plate panel and deriving electricity and heat therefrom;
transferring heat from the flat plate panel to a fluid circulated adjacent to the flat plate panel;
multiple axes tracking the flat plate panel to follow the sun so that the surface is kept essentially perpendicular to rays of the sun.

26. A method according to claim 25 wherein the impinging act comprises impinging rays of the sun aligned with the flat plate panel directly on the surface and deflecting rays adjacent to but not aligned with the surface onto the surface to thereby concentrate a greater amount of sunlight on the surface.

27. A method according to claim 26 further comprising the act of rotating the flat plate panel to face generally downward in times when there is little or no sunlight.

28. A method according to claim 25 further comprising the act of maintaining a low vertical profile of the flat plate panel and associated components.

29. A solar generator comprising:
a solar energy to electrical energy converter comprised of at least one surface upon which sunlight is impinged;
a cooling system associated with the converter but remote from the surface;
a bifunctional material interposed between the converter and the cooling system prohibiting transfer of electricity thereacross but accommodating transfer of thermal energy thereacross.

30. A solar generator according to claim 29 further comprising a light transmitting envelope encapsulating the solar generator in a hermetically sealed, evacuated environment.

31. A solar generator according to claim 29 further comprising at least one peripheral light deflector angular to but out of alignment with the one surface by which additional peripheral sunlight is concentrated on the one surface.
